(19) United States
(12) Patent Application Publication
(10) Pub. No.: US 2020/0381611 A1
(43) Pub. Date: Dec. 3, 2020

(54) PIEZOELECTRIC SENSOR

(71) Applicant: FATRI (Xiamen) Technologies Co., Ltd., Xiamen City (CN)

(72) Inventors: Yongzhong NIE, Xiamen City (CN); Chuan NIE, Xiamen City (CN)

(73) Assignee: FATRI (Xiamen) Technologies Co., Ltd., Xiamen City (CN)

(21) Appl. No.: 16/582,363

(22) Filed: Sep. 25, 2019

(30) Foreign Application Priority Data
Jun. 3, 2019 (CN) 201910476031.7

(51) Int. Cl. H01L 41/113; H01L 41/047; H01L 41/053; H01L 41/083; G01P 15/09

(52) U.S. Cl. CPC H01L 41/1132; H01L 41/0472; G01P 15/0907; H01L 41/053; H01L 41/0835; H01L 41/0475

(57) ABSTRACT

The disclosure provides a piezoelectric sensor, including a piezoelectric crystal cylinder including a plurality of crystal layers which are laminated, each crystal layer including two axially opposite end faces, each end face including an electrode film region and a terminal film region, wherein the electrode film region and the terminal film region on the same end face are separated by a crystal exposure region, the electrode film region on one end face of the two end faces in each crystal layer is electrically connected to the terminal film region on the opposite end face of the two end faces, and the electrode film regions on adjacent end faces of adjacent crystal layers are in contact with each other and form an electrical connection while the terminal film regions on the adjacent end faces of the adjacent crystal layers are in contact with each other and form an electrical connection.

### CROSS-REFERENCE TO RELATED APPLICATION

This application is based on and claims priority to Chinese Patent Application No. 201910476031.7 filed on Jun. 3, 2019, which is incorporated herein by reference in its entirety.

### TECHNICAL FIELD

The disclosure relates to the technical field of sensor, and in particular to a piezoelectric sensor.

### BACKGROUND

The signal output by the piezoelectric acceleration sensor is proportional to the vibration acceleration subjected to by the system. A piezoelectric acceleration sensor with high performance requirements, such as a standard piezoelectric acceleration sensor for calibrating an acceleration sensor, is generally required to have better linearity and stability and higher resonant frequency.

However, the existing piezoelectric acceleration sensor has low frequency response characteristics, insufficient overall contact stiffness, and weak stability.

Therefore, there is a need for a novel piezoelectric sensor.

### SUMMARY

Embodiments of the disclosure provide a piezoelectric sensor, which is intended to achieve high structural rigidity, small lamination size, and compact structure.

In an embodiment, the disclosure provides a piezoelectric sensor, including a piezoelectric crystal cylinder including a plurality of crystal layers which are laminated, each of the crystal layers including two end faces which are axially opposite, each of the two end faces including an electrode film region and a terminal film region, wherein the electrode film region and the terminal film region on the same end face are separated by a crystal exposure region, the electrode film region on one end face of the two end faces in each of the crystal layers is electrically connected to the terminal film region on the opposite end face of the two end faces, and the electrode film regions on adjacent end faces of adjacent crystal layers are in contact with each other and form an electrical connection while the terminal film regions on the adjacent end faces of the adjacent crystal layers are in contact with each other and form an electrical connection.

According to an aspect of an embodiment of the disclosure, each of the crystal layers includes a side electrode film layer on an outer peripheral surface thereof, and the electrode film region of one end face of the two end faces in each of the crystal layers is electrically connected to the terminal film region of the opposite end face of the two end faces through the side electrode film layer.

According to an aspect of an embodiment of the disclosure, an area occupied by the electrode film region is larger than an area occupied by the terminal film region in each of the two end faces.

According to an aspect of an embodiment of the disclosure, the electrode film regions on the two end faces in each of the crystal layers have opposite polarities.

According to an aspect of an embodiment of the disclosure, the piezoelectric sensor further includes a casing, a connecting member, and a mass block, wherein the casing is provided with a positioning hole, the piezoelectric crystal cylinder and the mass block are disposed within the casing, and the connecting member presses the piezoelectric crystal cylinder and the mass block against the casing in an axial direction of the piezoelectric crystal cylinder through the positioning hole.

According to an aspect of an embodiment of the disclosure, the connecting member includes a first connecting piece and a second connecting piece, a central through hole is provided in the piezoelectric crystal cylinder and the mass block, and the first connecting piece is securely coupled to the second connecting piece through the positioning hole and the central through hole.

According to an aspect of an embodiment of the disclosure, the casing is provide with a mounting hole which is disposed coaxially with the piezoelectric crystal cylinder and located at one end of the casing away from the positioning hole.

According to an aspect of an embodiment of the disclosure, the casing includes a plurality of casing portions, and the positioning hole and the mounting hole are respectively located in different casing portions of the casing.

According to an aspect of an embodiment of the disclosure, the piezoelectric sensor further includes a connector assembly, the casing is provided with a connector through hole through which the connector assembly is mounted to the casing, and the connector assembly is disposed to insulate from the casing.

According to an aspect of an embodiment of the disclosure, the connector assembly includes: a connector housing disposed to insulate from the casing; and a pin disposed to insulate from the connector housing and electrically connected to the piezoelectric crystal cylinder.

In the piezoelectric sensor according to the disclosure, the plurality of crystal layers in the piezoelectric crystal cylinder are laminated, and the electrical connection between the crystal layers is realized by the electrode film regions and the terminal film regions disposed on the crystal layers without separately providing an electrode layer. Therefore, the piezoelectric sensor according to the disclosure has improved rigidity, reduced lamination size, compact structure and good integrity.

### BRIEF DESCRIPTION OF THE DRAWINGS

The non-limiting embodiments are described in more detail below with reference to the drawings, wherein the same or similar reference numerals indicate the same or similar features.

FIG. 1 is a schematic structural view of a piezoelectric crystal cylinder of a piezoelectric sensor according to an embodiment of the disclosure;

FIG. 2 is a schematic plan view of a crystal layer of a piezoelectric sensor according to an embodiment of the disclosure;

FIG. 3 is a cross-sectional view taken along line A-A of the crystal layer of FIG. 2;

FIG. 4 is a schematic structural view of a piezoelectric crystal cylinder of a piezoelectric sensor according to an embodiment of the disclosure, in which a first side electrode and a second side electrode are shown;

FIG. 5 is a cross-sectional view showing partial structure of an embodiment of a piezoelectric crystal cylinder of a piezoelectric sensor according to an embodiment of the disclosure;

FIG. 6 is a cross-sectional view showing partial structure of another embodiment of a piezoelectric crystal cylinder of a piezoelectric sensor according to an embodiment of the disclosure; and

FIG. 7 is a cross-sectional view of a piezoelectric sensor according to an embodiment of the disclosure.

### DESCRIPTION OF REFERENCE NUMERALS

| | | | |
|---|---|---|---|
| 1 | piezoelectric crystal cylinder; | 11 | crystal layer; |
| 111 | electrode film region; | 112 | terminal film region; |
| 113 | side electrode film layer; | 12 | first side electrode; |
| 13 | second side electrode; | 2 | casing; |
| 3 | connecting member; | 31 | first connecting piece; |
| 32 | second connecting piece; | 4 | mass block; |
| 5 | insulating member; | 6 | sealing gasket; |
| 7 | connector assembly; | 71 | connector housing; |
| 72 | pin. | | |

### DETAILED DESCRIPTION

Features and exemplary embodiments of various aspects of the disclosure are described in detail below. In the following detailed description, numerous specific details are set forth to provide comprehensive understanding of the disclosure. However, it will be apparent to the skilled in the art that the disclosure may be practiced without some of the specific details. The following description of the embodiments is merely to provide a better understanding of the disclosure. In the drawings and the following description, at least some of the known structures and techniques are not shown, to avoid unnecessarily obscuring the disclosure. For clarity, the dimension of some of the structures may be enlarged. Furthermore, features, structures, or characteristics described hereinafter may be combined in any suitable manner in one or more embodiments.

The orientation terms appearing in the following description refer to the directions shown in the drawings, and are not intended to limit the specific structure of the embodiment of the disclosure. In the description of the disclosure, it should also be noted that, unless otherwise explicitly stated and defined, the terms “mount” or “connect” shall be understood broadly, for example, they may be fixed connection or detachable connection or integral connection; alternatively, they may be direct connection or indirect connection. The specific meaning of the above terms in the disclosure may be understood by the skilled in the art based on the specific situation.

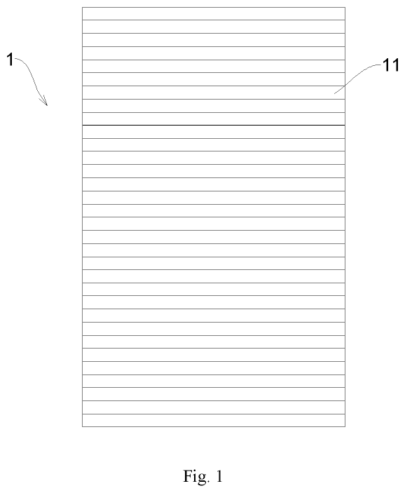

For a better understanding of the disclosure, a piezoelectric sensor according to an embodiment of the disclosure will be described in detail below with reference to FIGS. 1 to 7.

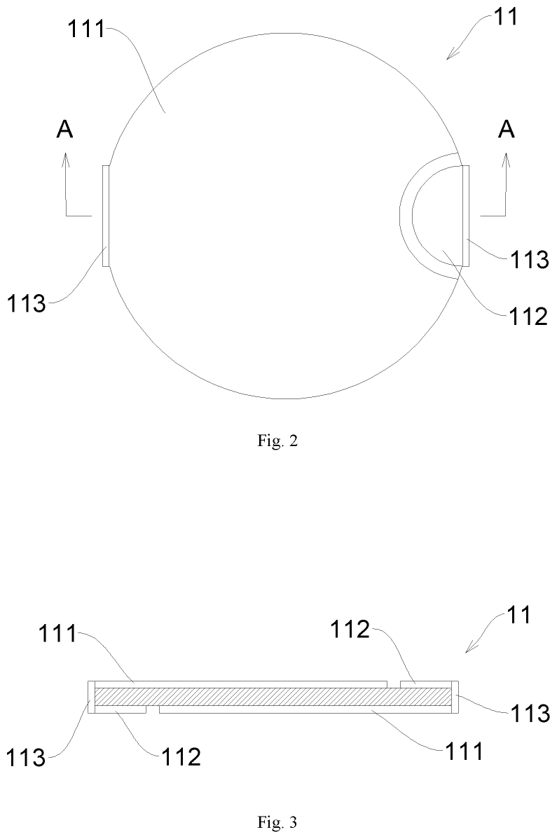

FIG. 1 is a schematic structural view of a piezoelectric crystal cylinder of a piezoelectric sensor according to an embodiment of the disclosure. FIG. 2 is a schematic plan view of a crystal layer of a piezoelectric sensor according to an embodiment of the disclosure. FIG. 3 is a cross-sectional view taken along line A-A of the crystal layer of FIG. 2. With Reference to FIGS. 1 to 3, the piezoelectric sensor according to the disclosure includes a piezoelectric crystal cylinder 1. The piezoelectric crystal cylinder 1 includes a plurality of crystal layers 11 which are laminated. Each of the plurality of crystal layers 11 includes two end faces which are opposite axially. Each of the two end faces includes an electrode film region 111 and a terminal film region 112. The electrode film region 111 and the terminal film region 112 on the same end face are separated by a crystal exposure region. The electrode film region 111 on one of the two end faces in each of the crystal layers 11 is electrically connected to the terminal film region 112 on the opposite one of the two end faces. The electrode film regions 111 on adjacent end faces of adjacent crystal layers 11 are in contact with each other and form an electrical connection, while the terminal film regions 112 on the adjacent end faces of the adjacent crystal layers 11 are in contact with each other and form an electrical connection.

According to an embodiment of the disclosure, the piezoelectric crystal cylinder 1 includes first and second ends which are axially opposite, and the plurality of crystal layers 11 are laminated along an axial direction of the piezoelectric crystal cylinder 1. The crystal layer 11 is a crystal plate having uniform thickness and may have any suitable cross-sectional shape including but not limited to, circular, rectangular, elliptical, and the like. The piezoelectric crystal column 11 formed by laminating the crystal layers 11 having uniform thickness has a higher overall rigidity, so that the piezoelectric sensor according to the embodiment of the disclosure has better stability. An intersecting edge is formed between the end face and the outer peripheral surface of the crystal layer 11. The crystal layer 11 may be made of any suitable piezoelectric material including but not limited to, Quartz single crystal, Lead Zirconate Titanate, Bismuth layered ceramic, Lithium Niobate, and the like. In one embodiment, the crystal layer 11 is made of the quartz single crystal having a sheet-like shape.

According to an embodiment of the disclosure, each of the two end faces in each of the crystal layers 11 is provided with the electrode film region 111 and the terminal film region 112 which are patterned. The electrode film region 111 and the terminal film region 112 of each end face are spaced apart by a crystal exposure region such that the electrode film region 111 and the terminal film region 112 of each end face are not in communication. In a specific embodiment, the electrode film region 111 and the terminal film region 112 are metal plating layers having extremely thin thickness. Since the thickness of the metal layer is set to be extremely thin, the thickness of the crystal layer 11 after being laminated is further reduced while electrical conduction is provided and the contact rigidity between the crystal layers 11 is further increased so that the rigidity of the piezoelectric crystal cylinder 1 is further increased.

According to an embodiment of the disclosure, in each end face, the area occupied by the electrode film region 111 is larger than the area occupied by the terminal film region 112. In one embodiment, in each end face of each of the crystal layers 11, the electrode film region 111, the terminal film region 112, and the crystal exposed region therebetween occupy the entire surface region of the end face. Intersecting regions, such as dots, lines or line segments, are respectively formed between the electrode film region 111 and the edge of the end face on which the electrode film region 111 is located, and between the terminal film region 112 and the edge of the end face on which the terminal film region 112 is located. In other words, the electrode film region 111 and the terminal film region 112 of the crystal layer 11 are partially exposed to the outer peripheral surface of the crystal layer 11, respectively.

According to an embodiment of the disclosure, each of the crystal layers 11 includes a side electrode film layer 113 on the outer peripheral surface thereof. An electrical connection is formed between the electrode film region 111 on one of the two end faces in each of the crystal layers 11 and the terminal film region 112 on the opposite one of the two end faces in each of the crystal layers 11 through the side electrode film layer 113. In each of the crystal layers 11, the number of the side electrode film layers 113 is two or more. In a specific embodiment, each of the crystal layers 11 includes two side electrode film layers 113 spaced apart on the outer peripheral surface thereof. Each side electrode film layer 113 includes two electrical connection terminals, one of which is electrically connected to the electrode film region 111 on one of the two end faces in the crystal layer 11 in which the side electrode film layer 113 is located, and the other of which is electrically connected to the terminal film region 112 on the opposite one of the two end faces in the crystal layer 11 in which the side electrode film layer 113 is located. In other words, through the side electrode film layer 113, an electrical connection is formed between the electrode film region 111 and the terminal film region 112 in different end faces of each crystal layer 11.

According to an embodiment of the disclosure, the electrode film regions 111 of the two end faces of each crystal layer 11 has opposite polarities.

According to an embodiment of the disclosure, the patterned film layers on adjacent end faces of the adjacent crystal layers 11 correspond to each other. In other words, the terminal film regions 112 are in contact with each other and form an electrical connection, and the electrode film regions 111 are in contact with each other and form an electrical connection. And, in the adjacent crystal layers 11, a pair of terminal film regions 112 contacting with each other and a pair of electrode film regions 111 contacting with each other are separated by the crystal exposure region.

In the piezoelectric sensor according to the disclosure, the plurality of crystal layers 11 in the piezoelectric crystal cylinder 1 are laminated, and the electrical connection between the crystal layers 11 is realized by the electrode film regions 111 and the terminal film regions 112 disposed on the crystal layers 1 without separately providing the electrode layer. Therefore, the piezoelectric crystal cylinder 1 has improved structural rigidity, reduced lamination size, compact structure, and good integrity.

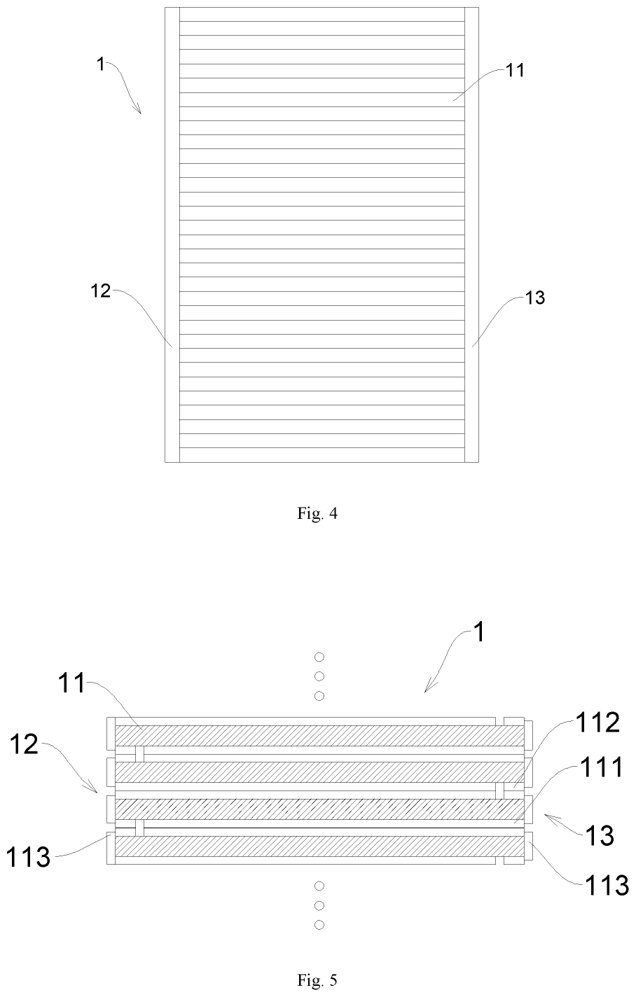

FIG. 4 is a schematic structural view of a piezoelectric crystal cylinder of a piezoelectric sensor according to an embodiment of the disclosure, in which a first side electrode and a second side electrode are shown. As shown in FIG. 4, according to one embodiment of the disclosure, a first side electrode 12 and a second side electrode 13 are formed on the outer peripheral surface of the piezoelectric crystal cylinder 1, and the first side electrode 12 and the second side electrode 13 are made of the side electrode film layers 113. The first side electrode 12 and the second side electrode 13 extend from a first end to a second end, respectively, and are spaced apart from each other on the outer peripheral surface of the piezoelectric crystal cylinder 1. A portion of the electrode film region 111 in the piezoelectric crystal cylinder 1 is electrically connected to the first side electrode 12, and the other portion of the electrode film region 111 is electrically connected to the second side electrode 13. The portion of electrode film region 111 electrically connected to the first side electrode 12 constitutes one plate of a shunt capacitor, and the portion of the electrode film region 111 electrically connected to the second side electrode 13 constitutes the other plate of the shunt capacitor. In one embodiment, the first side electrode 12 may function as a positive lead and the second side electrode 13 may serve as a negative lead. In another embodiment, the first side electrode 12 may function as a negative lead and the second side electrode 13 may serve as a positive lead.

FIG. 5 is a partial cross-sectional view showing an embodiment of a piezoelectric crystal column of a piezoelectric sensor according to an embodiment of the disclosure. As shown in FIG. 5, according to one embodiment of the disclosure, the first side electrode 12 or the second side electrode 13 is discontinuously disposed on the outer peripheral surface of the piezoelectric crystal cylinder 1. In other words, the plurality of side electrode film layers 113 constituting the first side electrode 12 (or the second side electrode 13) are not connected to each other, and the electrical connection is formed only by the corresponding electrode film regions 111 or the terminal film regions 112. Such discontinuous configuration can reduce the stress concentration of the first side electrode 12 and the second side electrode 13 in the axial direction, and can avoid the breakage of the first side electrode 12 and the second side electrode 13 in the axial direction to some extent, and thereby improving the stability and reliability of the sensor.

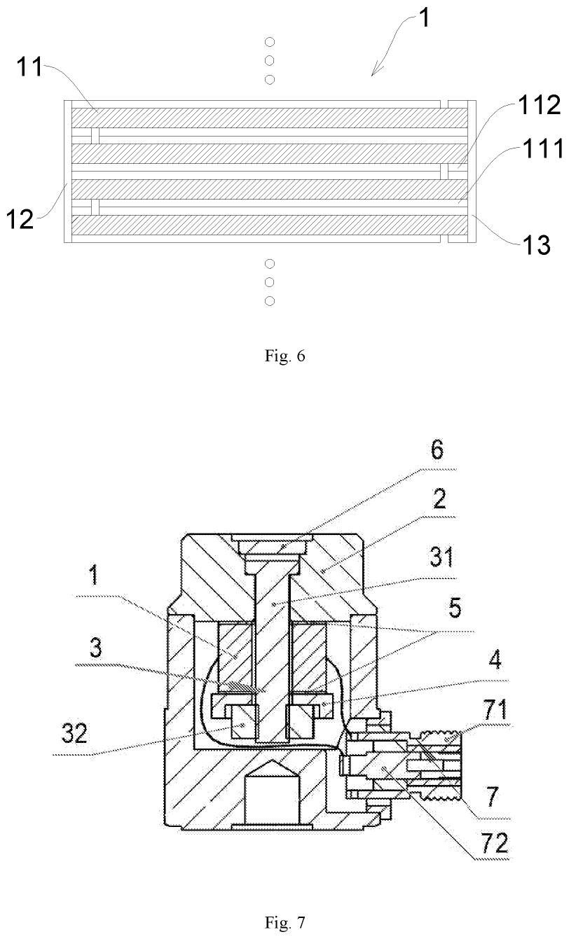

FIG. 6 is a partial cross-sectional view showing another embodiment of a piezoelectric crystal cylinder of a piezoelectric sensor according to an embodiment of the disclosure. As shown in FIG. 6, according to another embodiment of the disclosure, the first side electrode 12 or the second side electrode 13 is continuously disposed on the outer peripheral surface of the piezoelectric crystal cylinder 1. In other words, the plurality of side electrode film layers 113 constituting the first side electrode 12 (or the second side electrode 13) are sequentially connected to each other, and form the electrical connection together with the corresponding electrode film region 111 or the terminal film region 112. Such continuous configuration can integrally place the first side electrode 12 and the second side electrode 13 on the outer peripheral surface of the piezoelectric crystal cylinder 1, thereby providing the first side electrode 12 and the second side electrode 13 more conveniently.

According to an embodiment of the disclosure, the piezoelectric crystal cylinder 1 has a cylinder shape, and in another embodiment, the piezoelectric crystal cylinder 1 has a polygonal cylinder shape.

According to an embodiment of the disclosure, the outer peripheral surface of the piezoelectric crystal cylinder 1 includes a side electrode receiving portion for receiving the first side electrode 12 and/or the second side electrode 13. In one embodiment, the side electrode receiving portion is implemented as two flush cut surfaces disposed on the outer peripheral surface of the piezoelectric crystal cylinder 1, wherein the two cut flush surfaces extend respectively from the first end to the second end in the axial direction, and are spaced apart from each other. Preferably, the two flush cut surfaces are opposite in a radial direction of the piezoelectric crystal cylinder 1. The first side electrode 12 and the second side electrode 13 are respectively placed on the two flush cut surfaces, that is, the first side electrode 12 is placed corresponding to one flush cut surface and the second side electrode 13 placed corresponding to the other flush cut surface. The side electrode receiving portion may also be a curved cut surface or be implemented to conform to the contour of the outer peripheral surface of the piezoelectric crystal cylinder 1. By providing the side electrode receiving portion, it makes more easily displace the first side electrode 12 and the second side electrode 13, and facilitates alignment between the crystal layers 11 when the crystal layer 11 is laminated into the piezoelectric crystal column 1.

FIG. 7 is a cross-sectional view of a piezoelectric sensor according to an embodiment of the disclosure. As shown in FIG. 7, the piezoelectric sensor according to the disclosure further includes a casing 2, a connecting member 3 and a mass block 4. The casing 2 is provided with a positioning hole, and the piezoelectric crystal cylinder 1 and the mass block 4 are disposed within the casing 2. The connecting member 3 presses the piezoelectric crystal cylinder 1 and the mass block 4 against the casing 2 in the axial direction of the piezoelectric crystal cylinder 1 through the positioning hole. The piezoelectric crystal cylinder 1 is disposed between the mass block 4 and the casing 2, and two ends of the piezoelectric crystal cylinder 1 in the axial direction are respectively provided with insulating members 5. In other words, the insulating members 5 are respectively disposed between the piezoelectric crystal cylinder 1 and the casing 2, and between the piezoelectric crystal cylinder 1 and the mass block 4. The insulating member 5 may be an insulating gasket.

According to an embodiment of the disclosure, the connecting member 3 includes a first connecting piece 31 and a second connecting piece 32. A central through hole is provided in the piezoelectric crystal cylinder 1 and the mass block 4, and the first connecting piece 31 is securely coupled to the second connecting piece 32 through the positioning hole and the central through hole. The wall of the central through hole of the piezoelectric crystal cylinder 1 and the mass block 4 is disposed to insulate from or is gap-fitted with the first connecting piece 31. The first connecting piece 31 may be a bolt and the second connecting piece32 may be a mating nut. After the stem portion of the first connecting piece 31 passes through the positioning hole, the second connecting piece 32 engages with the thread on the stem portion of the first connecting piece 31. The first connecting piece 31 is provided with a shoulder portion which has a radial dimension of the shoulder portion larger than the diameter of the positioning hole, so that the first connecting piece 31 is limited at the positioning hole. Accordingly, the positioning hole may be provided with an annular groove for receiving the shoulder portion. Alternatively, the piezoelectric sensor according to the present embodiment may further include a sealing gasket 6, and the positioning hole of the casing 2 further includes a receiving portion for receiving the sealing gasket 6, specifically, an annular groove disposed at the positioning hole of the casing 2.

According to an embodiment of the disclosure, the casing 2 is provided with a mounting hole that is disposed coaxially with the piezoelectric crystal cylinder 1 and located at one end of the casing 2 away from the positioning hole. In other words, the mounting hole and the positioning hole are disposed adjacent to opposite ends of the piezoelectric crystal cylinder 1, and the region of the casing 2 where the mounting hole is located is away from the region of the casing 2 where the positioning hole is located. Thus, as shown in FIG. 1, in the orientation shown in FIG. 1, the piezoelectric crystal cylinder 1 is flip-chip mounted with respect to the mounting hole. As such, in the case where the piezoelectric sensor according to the present embodiment is mounted to the device under test through the mounting hole, the influence of the piezoelectric crystal cylinder 1 by the strain at the mounting hole can be reduced or even eliminated.

According to an embodiment of the disclosure, the casing 2 includes a plurality of casing portions, and the positioning hole and the mounting hole are disposed in different casing portions of the casing 2, respectively. As shown in FIG. 1, the casing 2 includes a first casing portion and a second casing portion, the positioning hole is provided in the first casing portion, and the mounting hole is provided in the second casing portion. The first casing portion and the second casing portion may be assembled into the casing 2. The first casing portion and the second casing portion may be detachably connected, such as by threaded connection. The portion of the casing 2 in which the positioning hole is located may be formed as a first base, where the positioning hole is located. The portion of the casing 2 in which the mounting hole is located may be formed as a second base, where the mounting hole. The first base and the second base are thicker relative to other portions of the casing 2.

The piezoelectric sensor according to the disclosure further includes a connector assembly 7, the casing 2 is provided with a connector through hole through which the connector assembly 7 is mounted to the casing 2, and the connector assembly 7 is disposed to insulate from the casing 2. A portion of the connector assembly 7 passes through the connector through hole into the casing 2 and the other portion of the connector assembly 7 is external to the casing 2. The connector through hole may be in the same portion of the casing 2 as the mounting hole, that is, both the connector through hole and the mounting hole are located in the second casing portion.

According to an embodiment of the disclosure, the connector assembly 7 includes a connector housing 71 and a pin 72, and the connector housing 71 is disposed to insulate from the casing 2 and electrically connected to one of the first side electrode 12 and the second side electrode 13. The pin 72 is disposed to insulate from the connector housing 71 and electrically connected to the other of the first side electrode 12 and the second side electrode 13. The connector assembly 7 may be a single core connector. The electrical connection between the connector assembly 7 and the first side electrode 12 and the electrical connection between the connector assembly 7 and the second side electrode 13 may be achieved by wires. The connector housing 71 and the casing 2 may be insulatingly fixed by means of glass sintering. The pin 72 and the connector housing 71 may be insulatingly fixed by means of glass sintering. The connector housing 71 is disposed to insulate from the casing 2 to isolate the casing 2 from the signal, thereby improving the external interference resistance of the piezoelectric sensor according to the present embodiment.

According to the piezoelectric sensor of the disclosure, the plurality of crystal layers 11 in the piezoelectric crystal cylinder 1 are laminated, and the electrical connection between the crystal layers 11 is realized by the electrode film regions 111 and the terminal film regions 112 disposed on the crystal layers 1 without separately providing the electrode layer, and therefore, the piezoelectric crystal cylinder 1 has improved structural rigidity, reduced lamination size, compact structure, and good integrity. Further, the mounting hole and the positioning hole are disposed at a relatively distant position, and therefore, when the piezoelectric sensor according to the present embodiment is mounted on the device under test through the mounting hole, the influence of the piezoelectric crystal cylinder 1 by the strain at the mounting hole can be reduced or even eliminated. Moreover, the connector housing 71 is disposed to insulate from the casing 2 to isolate the casing 2 from the signal, and therefore, the external interference resistance of the piezoelectric sensor according to the present embodiment can be improved.

It should be appreciated that the description of the specific embodiments of the disclosure is intended to be illustrative, and is not construed as limiting the scope of the disclosure. The scope of the disclosure is defined by the claims, and involves all the embodiments falling within the scope thereof and the obvious equivalents thereof.

What is claimed is:

1. A piezoelectric sensor, comprising:
a piezoelectric crystal cylinder comprising a plurality of crystal layers which are laminated, each of the crystal layers comprising two end faces which are axially opposite, each of the two end faces comprising an electrode film region and a terminal film region, wherein the electrode film region and the terminal film region on the same end face are separated by a crystal exposure region, the electrode film region on one end face of the two end faces in each of the crystal layers is electrically connected to the terminal film region on the opposite end face of the two end faces, and the electrode film regions on adjacent end faces of adjacent crystal layers are in contact with each other and form an electrical connection while the terminal film regions on the adjacent end faces of the adjacent crystal layers are in contact with each other and form an electrical connection.

2. The piezoelectric sensor according to claim 1, wherein each of the crystal layers comprises a side electrode film layer on an outer peripheral surface thereof, and the electrode film region of one end face of the two end faces in each of the crystal layers is electrically connected to the terminal film region of the opposite end face of the two end faces through the side electrode film layer.

3. The piezoelectric sensor according to claim 2, wherein an area occupied by the electrode film region is larger than an area occupied by the terminal film region in each of the two end faces.

4. The piezoelectric sensor according to claim 1, wherein the electrode film regions on the two end faces in each of the crystal layers have opposite polarities.

5. The piezoelectric sensor according to claim 1, further comprising a casing, a connecting member, and a mass block, wherein the casing is provided with a positioning hole, the piezoelectric crystal cylinder and the mass block are disposed within the casing, and the connecting member presses the piezoelectric crystal cylinder and the mass block against the casing in an axial direction of the piezoelectric crystal cylinder through the positioning hole.

6. The piezoelectric sensor according to claim 5, wherein the connecting member comprises a first connecting piece and a second connecting piece, a central through hole is provided in the piezoelectric crystal cylinder and the mass block, and the first connecting piece is securely coupled to the second connecting piece through the positioning hole and the central through hole.

7. The piezoelectric sensor according to claim 5, wherein the casing is provide with a mounting hole which is disposed coaxially with the piezoelectric crystal cylinder and located at one end of the casing away from the positioning hole.

8. The piezoelectric sensor according to claim 7, wherein the casing comprises a plurality of casing portions, and the positioning hole and the mounting hole are respectively located in different casing portions of the casing.

9. The piezoelectric sensor according to claim 5, further comprising a connector assembly, the casing is provided with a connector through hole through which the connector assembly is mounted to the casing, and the connector assembly is disposed to insulate from the casing.

10. The piezoelectric sensor according to claim 9, wherein the connector assembly comprises:
a connector housing disposed to insulate from the casing; and
a pin disposed to insulate from the connector housing and electrically connected to the piezoelectric crystal cylinder.
